(19) United States
(12) Patent Application Publication
(10) Pub. No.: US 2011/0241738 A1
(43) Pub. Date: Oct. 6, 2011

(54) SWITCHING DEVICE DRIVING UNIT AND SEMICONDUCTOR APPARATUS

(76) Inventor: Shuji TAMAOKA, Kyoto (JP)

(21) Appl. No.: 13/052,432

(22) Filed: Mar. 21, 2011

(30) Foreign Application Priority Data
Mar. 30, 2010 (JP) 2010-077390

(51) Int. Cl. H03K 17/00

(52) U.S. Cl. 327/109

(57) ABSTRACT

In order to provide a switching device driving unit that, even in a case where a threshold voltage of a switching device is varied, can suppress variations in switching speed, and prevent a power loss caused by an unnecessary gate current in a constant ON operation state of the switching device, so that a desired slew rate can be easily set, a control current source circuit sets to different values based on a first input driving signal, in a driving current to be source-outputted to a gate or a base of the switching device, a current in a stage of an initial ON operation of a switching operation of the switching device and a current in a stage after completion of the switching operation.

### FIELD OF THE INVENTION

The present invention relates to a switching device driving unit for drive-controlling a switching device to be installed in a semiconductor integrated circuit apparatus or the like, and to a semiconductor apparatus, and more particularly concerns such a switching device driving unit for drive-controlling (switch-driving) a switching device that allows a gate current or a base current to flow upon application of a bias voltage to a gate or a base, such as an FET in which a p-type region or a Schottkyelectrode is used for a gate, or a bipolar transistor, and to a semiconductor apparatus.

### BACKGROUND OF THE INVENTION

FIG. 6 is a block diagram that illustrates a conventional switching device driving unit disclosed in Japanese Unexamined Patent Publication No. 2009-11049.

The conventional switching device driving unit shown in FIG. 6 is suitably used for switch-driving a switching device with a gate terminal serving as a control terminal for an IGBT or MOS transistor being set to a high impedance. This switching device driving unit is designed to suppress variations in switching speed (slew rate of an output voltage) caused by variations in threshold voltage (mirror voltage) relative to the gate voltage of the switching device. The following description will discuss the conventional switching device driving unit.

As shown in FIG. 6, an output terminal of a switching device driving unit 51 is connected to the gate terminal of a switching device 50. The switching device driving unit 51 is provided with a determination/switching circuit 52 to which a gate control signal and a gate voltage of the switching device 50 are inputted, a constant-current pulse gate driving circuit 53 to which a control signal for an ON constant-current/OFF constant-current is inputted from the determination/switching circuit 52, and a constant-voltage pulse gate driving circuit 54 to which the control signal for an ON constant-voltage/OFF constant-voltage is inputted from the determination/switching circuit 52. The constant-current pulse gate driving circuit 53 is provided with an ON constant-current circuit and an OFF constant-current circuit, and the constant-voltage pulse gate driving circuit 54 is provided with an ON constant-voltage circuit and an OFF constant-voltage circuit. The respective outputs of the ON constant-current circuit, the OFF constant-current circuit, the ON constant-voltage circuit, and the OFF constant-voltage circuit in the switching device driving unit 51 are connective to the output terminal of the switching device driving device 51 so that an output signal from any one of the four constant-current/constant-voltage circuits is outputted to the gate of the switching device 50 on demand.

FIG. 7 is an operation explanatory view of the switching device driving unit 51 shown in FIG. 6. A gate driving signal, which is an output signal of the switching device driving unit 51, is switched to any one of four outputs of the ON constant-current circuit, the ON constant-voltage circuit, the OFF constant-current circuit, and the OFF constant-voltage circuit, in response to a gate control signal inputted to the switching device driving unit 51 and a gate voltage of the switching device 50. A slew rate of a rising or falling output voltage (that is, collector voltage of the switching device 50 shown in FIG. 7) at the time of an ON/OFF switching operation of the switching device 50 is determined by the gate current of the switching device 50 and a capacitance value between the gate and collector, although not shown in FIG. 6.

In the switching device driving unit 51 of FIG. 6, the gate of the switching device 50 is always constant-current-driven by the constant-current pulse gate driving circuit 53 at the time of the ON/OFF switching operation of the switching device 50 upon ON/OFF switching the gate control signal. For this reason, at the time of the ON/OFF switching operation of the switching device 50, the slew rate of the output voltage is not dependent on variations in threshold voltage (mirror voltage) of the switching device 50. Therefore, in the switching device driving unit 51 shown in FIG. 6, even when the threshold voltage (mirror voltage) relative to the gate voltage of the switching device 50 is varied, variations in switching speed that are greatly dependent on the slew rate value can be suppressed.

In order to set the slew rate of the output voltage of the switching device 50 to a desired value, it is necessary to set the constant-current value of the constant-current pulse gate driving circuit 33 constituted by the ON constant-current circuit and the OFF constant-current circuit to a considerably high value. For this purpose, a power-supply voltage for the ON constant-current circuit needs to be set to a higher value, and a GND voltage of the OFF constant-current circuit needs to be set to a negative voltage relative to an emitter voltage of the switching device 50. Therefore, in a case where the constant-current driving operation is continued as it is even after completion of a transition state of the switching device 50 from the ON state to the OFF state, or from the OFF state to the ON state, a great voltage in a forward direction or in a reverse direction is applied to the gate terminal of the switching device 50 to cause damages to a gate oxide film of the switching device 50, resulting in degradation of reliability of the device.

Taking this problem into consideration, the conventional switching device driving unit is designed so that, upon completion of the transition state of the switching device 50 from the ON state to the OFF state, or from the OFF state to the ON state, by switching from the ON constant-current circuit to the ON constant-voltage circuit, or from the OFF constant-current circuit to the OFF constant-voltage circuit, the driving system of the gate terminal of the switching device 50 is changed from the constant-current driving to the constant-voltage driving. In this manner, in the conventional switching device driving unit, the gate oxide film of the switching device is protected by clamping the gate terminal voltage.

As described above, in the conventional switching device driving unit, even when the threshold voltage of the switching device is varied, the switching speed of the switching device can be prevented from being varied, so that the gate oxide film of the switching device can be protected.

However, in a case where-there is used, as the switching device driven by the conventional switching device driving unit shown in FIG. 6, a switching device in which a gate current or a base current is allowed to flow upon application of a bias voltage to a gate or a base, such as an FET in which a p-type region or a Schottky electrode is used for a gate, or a bipolar transistor, serious problems as described below tend to occur.

FIG. 8 illustrates an equivalent circuit. diagram of an FET in which a p-type region or a Schottky electrode is used for a gate. As shown in FIG. 8, the FET in which the p-type region or the Schottky electrode is used for the gate is structured such that a diode is placed between the gate and a source as well as between the gate and a drain. Therefore, in the conventional switching device driving unit shown in FIG. 6, in a case where the PET shown in FIG. 8 is used as a switching device, a gate current is unnecessarily made to flow upon an operation of the constant-voltage circuit. Not only in the case of using the FET as the switching device, the same phenomenon occurs but also in the case of using the bipolar transistor.

Upon transition of the polarity of the output voltage of the switching device as described above by ON/OFF operating the switching device in the switching device driving unit, the gate current is required to operate the switching device at a desired switching speed (slew rate of the output voltage).

In a state where the gate terminal of a switching device is driven by the constant-voltage circuit of the conventional, switching device driving unit shown in FIG. 6, in other words, in a state where the switching device is completely set to the ON operation state or OFF operation state, no gate current is normally required for an IGBT or MOS transistor. Moreover, in the case of the FET or the like in which the p-type region or the Schottky electrode is used for the gate, a gate current used only for maintaining a VGS voltage for driving a drain current and a base current used only for driving a collector current are required in a constant ON operation state, and the aforementioned gate current that is allowed to flow to the gate terminal of the switching device during an operation in the constant-voltage circuit of the switching device driving unit causes an unnecessary power loss in the switching device and the switching device driving unit. This problem occurs in the same manner also in a case where the bipolar transistor is used as the switching device.

### SUMMARY OF THE INVENTION

In order to solve the above-mentioned problems with the conventional switching device driving unit, the present invention relates to a switching device driving unit that drives a switching device in which a gate current is allowed to flow upon application of a bias voltage to a gate, such as an FET in which a p-type region or a Schottky electrode is used for a gate, and an object thereof is to provide a switching device driving unit and a semiconductor apparatus which, even in a case where the threshold voltage of the switching device is varied, can suppress variations in slew rate of an output voltage of the switching device to prevent variations in switching speed and also prevent a power loss caused by an unnecessary gate current during a constant ON operation state of the switching device, so that a desired slew rate can be easily set. In addition to the FET in which the p-type region or the Schottky electrode is used for the gate, the present invent ion al so includes a bipolar transistor as the switching device.

In order to achieve the above object, according to a first aspect of the present invention, there is provided a switching device driving unit, which is connected to a gate or a base of a switching device that requires a gate current or a base current so as to drive a load, and outputs a driving current for ON/OFF operating the switching device based on an inputted gate control signal to the gate or the base, the switching device driving unit including: a control current source circuit that is connected to a power supply side, and source-outputs a driving current to the gate or the base in response to an H level or an L level of the gate control signal; a control current sink circuit that is connected to a ground side, and sink-outputs a driving current to the gate or the base in response to the L level or the H level of the gate control signal; and an I/F circuit to which the gate control signal is inputted and which generates a first driving signal to be applied to the control current source circuit and a second driving signal to be applied to the control current sink circuit, wherein based on the first driving signal, the control current source circuit sets the driving current to be source-outputted to the gate or the base of the switching device to different values in a stage of an initial ON operation of the switching operation in the switching device as well as in a stage after completion of the switching operation. In such a switching device driving unit of the first aspect thus structured, upon transition from the OFF state to the ON state of the switching device by using a gate control signal, a slew rate (switching speed) of the output voltage of the switching device can be set to a desired value. The first driving signal and the second driving signal according to the first aspect are respectively exemplified as an input driving signal CUD) and an input driving signal (LD), in “Detailed Description of the Preferred Embodiments”, which will be described later.

In a switching device driving unit according to a second aspect of the present invention, the switching device in the first aspect may be an FET that uses a p-type region or a Schottky electrode for a gate, or a bipolar transistor. In a case where, upon completion of the switching operation, the switching device is brought into a constant ON operation state, the switching device driving unit according to the second aspect thus structured can set the gate current or the base current required for maintaining load driving, which is an inherent characteristic of the FET in which the p-type region or the Schottky electrode is used for the gate, or the bipolar transistor, to an appropriate current value.

In a switching device driving unit according to a third aspect of the present invention, in the first aspect, in a first stage of initial output, the control current source circuit may maintain the driving current to be source-outputted to the gate or the base of the switching device at a first constant-current value to be set so as to allow the switching operation of the switching device to have a predetermined speed, and in a second stage after a lapse of a predetermined delay period of time in an ON state after completion of the switching operation of the switching device, the control current source circuit may alter the driving current to a second constant-current value having a value smaller than the first constant-current value, which is required for allowing the switching device to maintain load driving. The switching device driving unit of the third aspect thus structured drives the gate current or the gate current of the switching device by using the constant-current, so that the slew rate is prevented from being dependent on variations of the threshold voltage of the switching device.

In a switching device driving unit according to a fourth aspect of the present invention, in the third aspect, the control current source circuit has a plurality of source-use constant-current supplies, and a source output from one of the plurality of source-use constant-current supplies to the gate or the base of the switching device is ON/OFF controlled in response to a first driving signal inputted to the control current source circuit, and a source output from another one of the source-use constant-current supplies to the gate or the base of the switching device is ON/OFF controlled in response to a third driving signal that is obtained by waveform-shaping from the first driving signal inputted to the control current source circuit and a delay signal formed by delaying the first driving signal by a predetermined period of time. The switching device driving unit of the fourth aspect thus structured can set, when, upon completion of the switching operation, the switching device is brought into a constant ON operation state, the gate current or the base current required for maintaining load driving to the appropriate current value, and drives the gate current or the base current of the switching device by the constant-current, so that the slew rate is prevented from being dependent on variations of the threshold voltage of the switching device. The first driving signal, the third driving signal, and the delay signal according to the fourth aspect are respectively exemplified as an input driving signal (UD), a driving signal (UD2) , and a signal (UDL) in “Detailed Description of the Preferred Embodiments”, which will be described later.

In a switching device driving unit according to a fifth aspect of the present invention, in the first aspect, the control current sink circuit maintains the driving current to be sink-outputted to the gate or the base of the switching device at a third constant-current value set so as to allow the switching operation of the switching device to have a predetermined speed in a first stage of initial output, and in a second stage after a lapse of a predetermined delay period of time in an OFF state after completion of the switching operation of the switching device, brings the driving current into a low impedance state having a current capability enough to absorb a capacitive current that flows through the gate or the base. The switching device driving unit of the fifth aspect thus structured can set, upon transition from the ON state to the OFF state of the switching device by using the gate control signal, the slew rate (switching speed) of the output voltage of the switching device to the desired value. Moreover, since the gate current or the base current of the switching device can be driven by the constant-current, the slew rate is prevented from being dependent on variations of the threshold voltage of the switching device.

In a switching device driving unit according to a sixth aspect of the present invention, in the fifth aspect, the control current sink circuit has a sink-use constant-current supply for discharging a charge of the gate or the base of the switching device, and a sink transistor that has the current capability enough to absorb the capacitive current that flows through the gate or the base of the switching device in the OFF state of the switching device, and a sink output from the sink-use constant-current supply to the gate or the base of the switching device is ON/OFF controlled in response to the second driving signal inputted to the control current sink circuit, and the sink transistor is ON/OFF controlled by a fourth driving signal that is waveform-shaped from the second driving signal inputted to the control current sink circuit and a delay signal formed by delaying the second driving signal by a predetermined period of time. The capacitive current refers to a current that flows into the gate or the base through a capacitance between the drain and the gate or a capacitance between the collector and the base of the switching device. The switching device driving unit of the sixth aspect thus structured can maintain, when the switching device is brought into a constant OFF operation state by the function of the sink transistor of the control current sink circuit, even in a case where the capacitive current flows into the gate or the base through the capacitance between the drain and the gate or the capacitance between the collector and the base of the FET or the bipolar transistor, the gate voltage or the base voltage of the switching device at the voltage of the OFF state of the switching device. This effect is useful for avoiding a danger of shoot-through (through mode) in which two switching devices on a low-voltage side and a high-voltage side are simultaneously ON-operated in a semi-bridge, an H-bridge, a three-phase inverter circuit or the like having a structure in which a pair of semiconductor apparatuses, each constituted by a switching device driving unit and a switching device, are installed in series with each other on two stages of the low voltage side and the high voltage side. The second driving signal, the fourth driving signal, and the delay signal according to the six aspect are respectively exemplified as an input driving signal (LD) , a driving signal (LD2), and a signal (LDL), in “Detailed. Description of the Preferred Embodiments”, which will be described later.

In a switching device driving unit according to a seventh aspect of the present invention, in the first aspect, there is further provided: a hysteresis comparator that has two threshold voltages of a H level and a L level, and compares a gate voltage or a base voltage of the switching device inputted to an inversion input terminal with the threshold voltages, wherein an output from the hysteresis comparator is inputted to the control current source circuit and the control current sink circuit so as to control, in response to the gate voltage or the base voltage of the switching device, a driving current from the control current source circuit and the control current sink circuit to the gate or the base of the switching device. The switching device driving unit of the seventh aspect thus structured can set, upon transition from the OFF state to the ON state or from the ON state to the OFF state of the switching device by using the gate control signal, the slew rate (switching speed) of the output voltage of the switching device to a desired value.

In a switching device driving unit according to an eighth aspect of the present invention, in the seventh aspect, in a first stage of initial output, the control current source circuit maintains the driving current to be source-outputted to the gate or the base of the switching device at a first constant-current value to be set so as to allow the switching operation of the switching device to have a predetermined speed, and in a second stage in which the gate voltage or the base voltage of the switching device exceeds the threshold voltage of the H level of the hysteresis comparator, the control current source circuit alters the driving current to a second constant-current value smaller than the first constant-current value, which is required for allowing the switching device to maintain load driving. The switching device driving unit of the eighth aspect thus structured can set when, upon completion of the switching operation, the switching device is brought into a constant ON operation state, the gate current or the base current required for maintaining load driving to the appropriate current value, thereby making it possible to out unnecessary power.

In a switching device driving unit according to a ninth aspect of the present invention, in the eighth aspect, the control current source circuit has a plurality of source-use constant-current supplies, and a source output from one of the plurality of source-use constant-current supplies to the gate or the base of the switching device is ON/OFF controlled in response to the first driving signal inputted to the control current source circuit, and a source output to the gate or the base of the switching device from another one of the source-use constant-current supplies is ON/OFF controlled when the gate voltage or the base voltage of the switching device exceeds the threshold voltage of the H level of the hysteresis comparator. The switching device driving unit of the ninth aspect thus structured drives the gate current or the base current of the switching device by the constant-current, so that the slew rate is prevented from being dependent on variations of the threshold voltage of the switching device. The first driving signal according to the ninth aspect is exemplified as an input driving signal (UD) in “Detailed Description of the Preferred Embodiments”, which will be described later.

In a switching device driving unit according to a tenth aspect of the present invention, in the seventh aspect, the control current sink circuit maintains the driving current to be sink- outputted to the gate or the base of the switching device at a third constant-current value to be set so as to allow the switching operation of the switching device to have a predetermined speed in a first stage of initial output, and in a second stage in which the gate voltage or the base voltage of the switching device is lower than the threshold voltage of the L level of the hysteresis comparator, brings the driving current into a low impedance state having a current capability enough to absorb a capacitive current that flows through the gate or the base when the switching device is in an OFF state. The switching device driving unit of the tenth aspect thus structured can set, upon transition from the ON state to the OFF state of the switching device by using the gate control signal, the slew rate (switching speed) of the output voltage of the switching device to the desired value. Moreover, since the gate current or the base current of the switching device is driven by the constant-current, the slew rate is prevented from being dependent on variations of the threshold voltage of the switching device.

In a switching device driving unit according to an eleventh aspect of the present invention, in the tenth aspect, the control current sink circuit has a sink-use constant-current supply for discharging a charge of the gate or the base of the switching device, and a sink transistor that has the current capability enough to absorb the capacitive current that flows through the gate or the base of the switching device in an OFF state of the switching device, and a sink output from the sink-use constant-current supply to the gate or the base of the switching device is ON/OFF controlled in response to the second driving signal inputted to the control current sink circuit, and the sink transistor is ON/OFF controlled when the gate voltage or the base voltage of the switching device is lower than the threshold voltage of the L level of the hysteresis comparator. The capacitive current refers to a current that flows into the gate or the base through the capacitance between the drain and the gate or the capacitance between the collector and the base of the switching device. The switching device driving unit of the eleventh aspect thus structured can maintain, when the switching device is brought into a constant OFF operation state by the function of the sink transistor of the control current sink circuit, even in a case where the capacitive current flows into the gate or the base through the capacitance between the drain and the gate or the capacitance between the collector and the base of the FET or the bipolar transistor, the gate voltage or the base voltage of the switching device at the voltage of the OFF state of the switching device. This effect is useful for avoiding a danger of shoot-through (through mode) in which two switching devices on a low-voltage side and a high-voltage side are simultaneously ON-operated, in a semi-bridge, an H-bridge, a three-phase inverter circuit or the like having a structure in which a pair of semiconductor apparatuses, each constituted by a switching device driving unit and a switching device, are installed in series with each other on two stages of the low voltage side and the nigh voltage side. The second driving signal according to the eleventh aspect is exemplified as an input driving signal (LD) in “Detailed Description of the Preferred Embodiments”, which will be described later.

A semiconductor apparatus according to a twelfth aspect of the present invention can include: the switching device driving unit in any one of the first to eleventh aspects; and a switching device that is drive-controlled by the switching device driving unit. In the switching device driving unit of the twelfth aspect thus structured, even in a case where the threshold voltage of the switching device is varied, the switching speed of the switching device is prevented from being varied, a power loss due to the gate current unnecessary in a constant ON operation state of the switching device can be prevented, a desired slew rate can be easily set, so that the device has high reliability with energy consumption being cut.

The novel features of the present invention are intended to be limited on y by those particularly described in the attached claims, and both of the structure and contents of the present invention together with the other objects and features will be well understood and evaluated from the following detailed description of the present invention when taken in conjunction with the accompanying drawings.

In the switching device driving unit of the present invention, by driving at a constant-current the gate or base of a switching device serving as a drive-controlling subject, even in a case where the threshold voltage serving as an operational point of the switching device is varied, variations in slew rate of the output voltage of the switching device upon transition from the OFF state to the ON state or from the ON state to the OFF state can be suppressed, so that variations in switching speed can be suppressed, and by preventing a power loss due to an unnecessary gate current or a base current in the constant ON operation state of the switching device, a desired slew rate can be easily set effectively. The switching device driving unit of the present invention can be further effectively used particularly in such a switching device driving unit in which a gate current or a base current is required to drive a load, such as an FET in which a p-type region or a Schottky electrode is used for a gate, or a bipolar transistor.

### BRIEF DESCRIPTION OF THE DRAWINGS

The present invention will become more fully understood from the detailed description and the accompanying drawings, wherein:

FIG. 1 is a block diagram that illustrates a specific structure of a first embodiment of a switching device driving unit in accordance with the present invention;

FIG. 2 is a timing waveform diagram that illustrates a relationship among signals and the like in the switching device driving unit in accordance the first embodiment;

FIG. 3 is a circuit diagram that illustrates a specific structure of a constant-current supply for a control current source circuit in a switching device driving unit in accordance with the first embodiment or a second embodiment;

FIG. 4 is a block diagram that illustrates a specific structure of the second embodiment of the switching device driving unit in accordance with the present invention;

FIG. 5 is a timing waveform diagram that illustrates a relationship among signals and the like in the switching device driving unit in accordance the second embodiment; FIG. 6 is a block diagram that illustrates a structure of a conventional switching device driving unit;

FIG. 7 is an explanatory view that illustrates operations of the conventional switching device driving unit; and

FIG. 6 is an equivalent circuit diagram of an FET in which a p-type region or a Schottky electrode is used for a gate.

### DETAILED DESCRIPTION OF THE PREFERRED EMBODIMENTS

Referring to attached drawings, the following description will discuss in detail preferred embodiments of a switching device driving unit according to the present invention, and a semiconductor apparatus provided with such a switching device driving unit and a switching device. The present invention is not intended to be limited to specific structures described in the following embodiments, but also includes those structures formed based on the technical ideas same as those described in the preferred embodiments and technical common knowledge in the corresponding technical field.

### First Embodiment

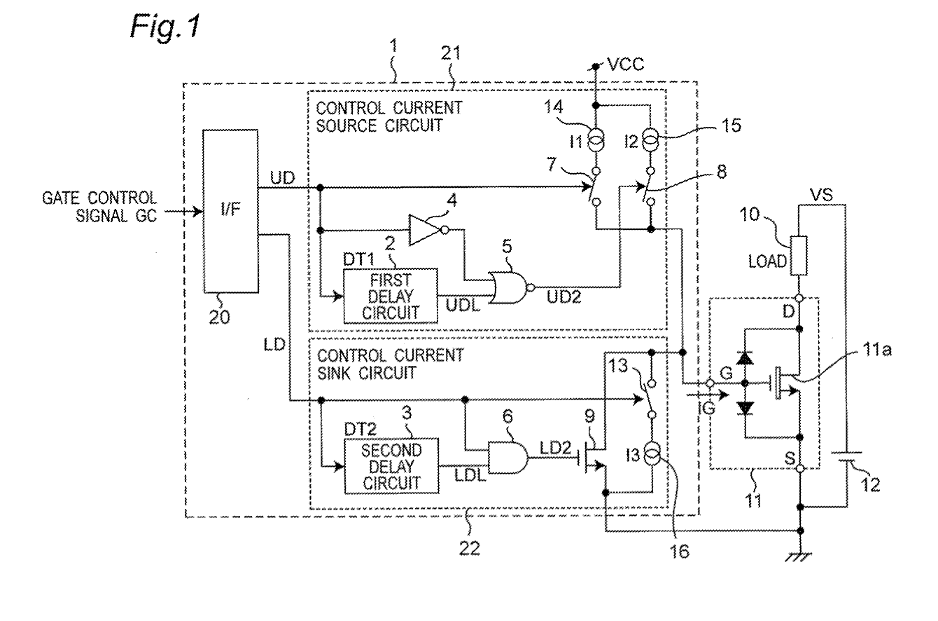

FIG. 1 is a block diagram that illustrates a specific structure of a first embodiment of a switching device driving unit and a semiconductor apparatus in accordance with the present invention. Referring to FIG. 1, the following description will discuss the first embodiment of the switching device driving unit in accordance with the present invention.

A switching device driving unit 1, which ON/OFF drives (carries out switching operations) a switching device 11, is constituted by an I/F (interface) circuit 20 to which a gate control signal (GC) is inputted, a control current source circuit 21 to which a signal (US) is inputted from the I/F circuit 20 and which is connected to a power supply side (VCC) , and a control current sink circuit 22 to which a signal (LD) is inputted from the I/F circuit 20 and which is connected to a ground. Outputs from the control current source circuit 21 and the control current sink circuit 22 are inputted to a gate terminal (G) of the switching device 11 as the outputs of the switching device driving unit 1. In the first embodiment, the switching device 11 is exemplified by an FET 11a in which a p-type region or a Schottky electrode is used for a gate; however, a bipolar transistor may be applicable as the switching device 11 that is ON/OFF driven by the switching device driving unit of the present invention.

In the switching device driving unit 1 of the first embodiment, the I/F circuit 20, to which the gate control signal (GC) is inputted, generates an input driving signal (UD) for the control current source circuit 21 and an input driving signal (LD) for the control current sink circuit 22. In response to an H level or an L level of the input driving signal (UD) inputted thereto, the control current source circuit 21 outputs (source-outputs) a gate current (IC) to the gate terminal (G) of the FET 11a of the switching device 11. In response to an L level or an H level of the input driving signal (LD) inputted thereto, the control current sink circuit 22 outputs (sink-outputs) a gate current (IG) to the gate terminal (G) of the FET 11a of the switching device 11. In this manner, the respective outputs of the control current source circuit 21 and the control current sink circuit 22 are connected to the gate terminal (G) of the FET 11a via the output terminal of the switching device driving unit 1.

The control current source circuit 21 is provided with two constant-current supplies 14 and 15. A switch circuit 7, which is drive-controlled by the input driving signal (UD), is installed on one of the constant-current supplies 14 so that a constant-current (I1) of the constant-current supply 14 is source-outputted to the gate terminal (G) of the FET 11a in response to the input driving signal (UD). A switch circuit 8, which is drive-controlled by a driving signal (UD2) obtained by waveform-shaping from the input driving signal (UD) and a signal (UDL) obtained by delaying the input driving signal (UD) by a predetermined delay time DT1, is installed on the other constant-current supply 15. The switch circuit 8 is drive-controlled by the driving signal (UD2), so that a constant-current (I2) of the constant-current supply 15 is source-outputted to the gate terminal (G) of the FET 11a simultaneously with the constant-current (I1), and so that the supply to the gate terminal (G) of the FET 11a is cut off after the predetermined delay time DT1 has been elapsed.

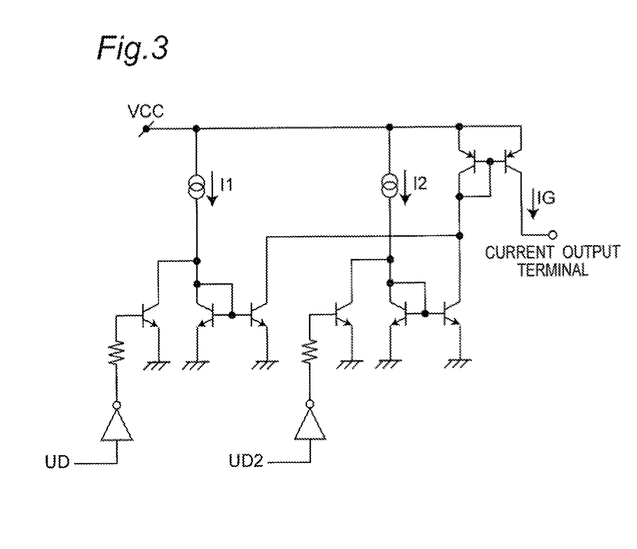

In FIG. 1, the circuit structure for source-outputting to the gate terminal (G) of the FET 11a by using the two constant-current supplies 14 and 15 and the switching circuits 7 and 8 of the control current source circuit 21 in the switching device driving unit 1 of the first embodiment has been described; however, more specifically, a circuit structure shown in FIG. 3 can be exemplified.

The circuit structure shown in FIG. 3 is provided with two constant-current supplies (I1, I2) and a plurality of bipolar-type transistors, and has a structure to which driving signals (UD, UD2) are inputted so that a gate current (IG) is outputted from one current output terminal. FIG. 3 exemplifies a structure in which the gate current (IG) is controlled by the driving signals (UD, UD2) by the use of the plurality of the bipolar-type transistors; however, these bipolar-type transistors may be replaced by MOS-type transistors and the same effects can be obtained.

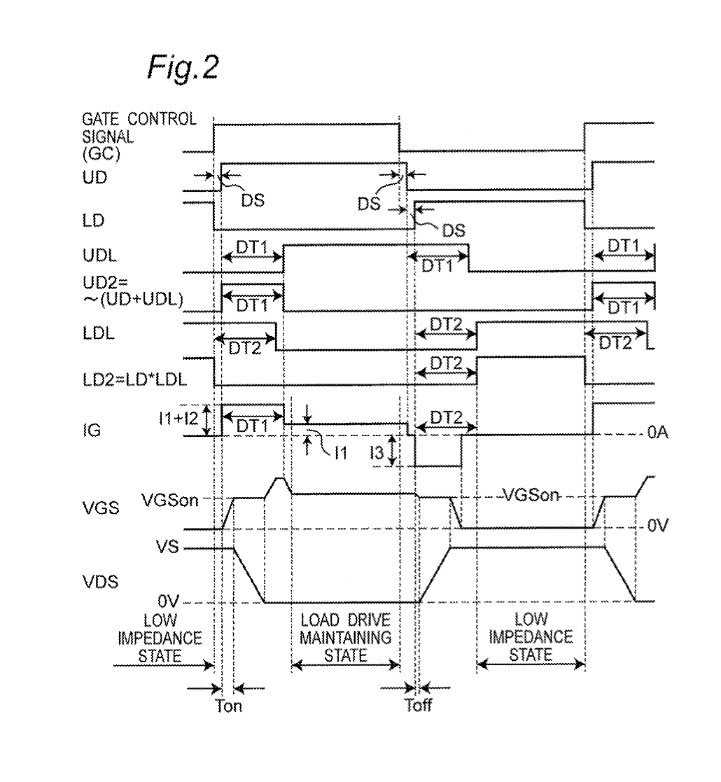

FIG. 2 is a timing waveform diagram that shows a relationship among the gate control signal (GC), the driving signals (UD, LD, UDL, UD2), the gate current (IG), the constant-currents (I1, I2) and the like. By using the timing waveform diagram of FIG. 2, the following description will discuss a mechanism by which the gate current (IG) of the gate terminal (G) of the FET 11a serving as he switching device 11 is source-outputted, in detail.

In the switching device driving unit 1 of the first embodiment of the present invention, the timing waveform diagram of FIG. 2 exemplifies a structure in which, when the gate control signal (GC) is in the H level, the gaze current (IG) is source-outputted; however, another structure in which, when the gate control signal (GC) is in the L level, the gate current (IG) is source-outputted may be adopted.

Moreover, in the switching device driving unit of the first embodiment, the polarity of each of signals shown in FIG. 2 is not necessarily required to be the same polarity as that indicated in FIG. 2, but may have a reversed polarity to that shown therein; emotively, the relative polarity relationship among the respective signals is not necessarily required to be the same polarity relationship as that indicated in FIG. 2. This is because the specific polarity relationship among these signals relates to means for achieving the object of the present invention, that, is circuit designing for the control current source circuit 21 and the control current sink circuit 22, and does not relate to the object of the switching device driving unit of the present invention.

As shown in the timing waveform diagram of FIG. 2, in a case where the gate control signal (GC) becomes a H level, the I/F circuit 20 sets the input driving signal (LD) of the control current sink circuit 22 to a L level, and after a lapse of a predetermined period of delay time DS from that point of time, it also sets the input driving signal (UD) of the control current source circuit 21 to the H level. In the control current source circuit 21 and the control current sink circuit 22, when the input driving signals (UD, LD) are in the H level, the respective operations are made active so that the respective constant-currents I1, I2 and I3 are ready to be outputted.

The reason why the I/F circuit 20 carries out a switching process with a shift by the delay time DS so as not to be overlapped, without simultaneously switching the polarities of the respective input driving signals (UD, LD) , is because it is necessary to avoid the control current source circuit 21 and the control current sink circuit 22 from simultaneously outputting constant-currents. However, in this case where no problems are raised even if the constant-currents are simultaneously outputted by the control current source circuit 21 and the control current sink circuit 22, simultaneously as the gate control signal (GC) becomes the H level, the I/F circuit 20 may set the input driving signal (LD) of the control current sink circuit 22 to the L level, with the input driving signal (UD) of the control current source circuit 21 being simultaneously set to the H level.

When the input driving signal (UD) is set to the H level, the constant-current I1 is outputted to the gate terminal (G) of the FET 11a through the switching circuit 7. A signal (UDL), formed by delaying the input driving signal (UD) by a delay time DT1 by using the inversion signal of the input driving signal (UD) and the first delay circuit 2, is inputted to a 2-input NOR circuit 5 so that a driving signal (UD2) is formed.

The driving signal (UD2) corresponds to a signal that becomes the H level only during the delay time DT1 from the rising edge of the input driving signal (UD). Only during the period of the H level of this signal (UD2), the constant-current 12 is outputted to the gate terminal (G) of the FET 11a.

After a lapse of the delay time DS after the gate control signal (GC) has become the H level as the results of the functions as described above, a gate current (IG) indicated by the following equation (1) is allowed to flow into the gate terminal (G) of the FET 11a.

IG=I1+I2 (1)

After a lapse of the delay time DT1 since the gate current (IG) has been allowed to flow into the gate terminal (G) of the FET 11a as described above, a gate current (IG) indicated by the following equation (2) is allowed to flow into the gate terminal (G).

IG=I1 (2)

As described earlier, during the period of the H level of the gate control signal (GC), the input driving signal (LD) becomes the L level so that the constant-current I3 of the control current sink circuit 22 is not outputted to the gate terminal (G) of the FET 11a.

Next, when the gate control signal (GC) changes to the L level, the input driving signal (UD) becomes the L level after a lapse of the delay time DS, and the input driving signal (LD) becomes the H level after the delay time DS has further elapsed. This is because, in the same manner as described earlier, it is necessary to avoid the control current sink circuit 22 and the control current source circuit 21 from being simultaneously brought into the output state. If no problems are raised even when the control current source circuit 21 and the control current sink circuit 22 are allowed to simultaneously output, the I/F circuit 20 may set the input driving signal (UD) of the control current source circuit 21 to the L level, with the input driving signal (LD) of the control current sink circuit 22 being simultaneously set to the H level.

As clearly understood by FIG. 1, the driving signal (UD2) is always set to the L level when the input driving signal (UD) becomes the L level no that the constant-currents I1 and I2 of the control current sink circuit 22 are not outputted to the gate terminal (G) of the FET 11a. In contrast, when the input driving signal (LD) becomes the H level, the constant-current I3 of the control current sink circuit 22 is outputted to the gate terminal (G) of the FET 11a.

The input driving signal (LD) and a signal (LDL) formed by delaying the input driving signal (LD) by a delay time DT2 by using a second delay circuit 3, are inputted to a 2-input AND circuit 6 so that a driving signal (LD2) is formed based on an AND logic . The driving signal (LD2) thus formed corresponds to a signal obtained by delaying the input driving signal (LD) by the delay time DT2 from the rising edge of the input driving signal (LD). The falling edges of the input driving signal (LD) and the driving signal (LD2) have the same timing. Only during the H level of the driving signal (LD2), the gate voltage of the sink transistor 9 becomes the H level, thereby setting the sink transistor 9 to the ON state.

After a lapse of two times the delay time DS after the gate control signal (GC) has become the L level as the results of the functions as described above, that is, from the time at which the input driving signal (LD) has risen to the H level, a gate current (IG) indicated by the following equation (3) is drawn from the gate terminal (G) of the FET 11a.

IG=I3 (3)

After a lapse of the delay time DT2 since the rising of the input driving signal (LD) to the H level after the gate current (IG) has been drawn from the gate terminal (G) of the FET 11a as described above, the sink transistor 9 is set to the ON state so that the gate terminal (G) is brought to a low impedance state having a high sink current capability so as to be fixed to a virtually GND voltage.

In the switching device driving unit of the first embodiment of the present invention, the values of the constant-currents I1, I2 and I3, and the delay time DT1 of the first delay circuit 2, and the delay time DT2 of the second delay circuit 3 are designed to be desirably set. Therefore, the switching device driving unit of the first embodiment of the present invention makes it possible to suppress variations in slew rate of the output voltage of the FET 11a, even when the threshold voltage of the FET 11a in which a p-type region or a Schottky electrode is used for a gate is varied upon transition from the OFF state to the ON state, or from the ON state to the OFF state, thereby making it possible to suppress variations in switching speed.

Moreover, in the switching device driving unit of the first embodiment constructed as described above, it is possible easily set the slew rate of the output voltage to a desired value, upon transition from the OFF state to the ON state or upon transition from the ON state to the OFF state of the FET 11a.

Furthermore, in the switching device driving unit of the first embodiment, by the constant ON operation state of the FET 11a serving as the switching device, an unnecessary gate current (IG) is prevented from flowing to the gate terminal (G) of the FET 11a so that a power loss can be prevented.

In the switching device driving unit of the first embodiment, the following description will discuss an operational principle based on which variations of the switching speed can be suppressed, the slew rate of the output voltage can be easily set, and the power loss in the constant ON operation state of the switching device can be prevented, as described above.

When, as shown in FIG. 2, the gate control signal (GC) is changed from the L level to the H level, with one of input driving signals (LD) being set to the L level, the other input driving signal (UD) becomes the t level after a lapse of the delay time DS. In a case where the input driving signal (US) becomes the H level in this manner, a gate current (IG) starts flowing into the gate terminal (G) of the FET 11a. At this time, the gate current (IC) forms the current value (I1+I2) as indicated by the equation (1). As a result, the gate terminal voltage is raised by the flowing-in gate current (IC) to gradually set the FET 11a to the ON state so as to reach a VGSon voltage (see FIG. 2) by which the ON operation is initiated. From this point of time, the FET 11a is allowed to reach the ON operation state which completely drives a load 10, through a transition state in which the load 10 connected to the drain terminal (D) is started to be driven.

On the other hand, the drain voltage (VDS), which is an output voltage of the FET 11a, becomes the voltage (VS) of the power supply 12 which is connected with the other edge of the load 10 in the OFF state of the FET 11a. In an ON operation state of the FET 11a, the drain voltage (VDS) of the FET 11a reaches an ON voltage which is determined by an ON resistance of the FET 11a and a voltage (VS) of the load 10. The ON voltage is a voltage close to 0V.

The falling slew rate of the output voltage (drain voltage) of the FET 11a, described here, means a time-based inclination in which the drain voltage (VDS) of the FET 11a has reached the ON voltage from the voltage (VS). In the transit state in which the gate voltage of the FET 11a has reached the VGSon voltage to allow the FET 11a to start driving the load 10, the gate current (IG) does not supply the gate capacitance (not shown) of the FET 11a with a charge, and since the drain voltage of the FET 11a starts dropping from a voltage (VS) toward the ON voltage, most of the gate current (IG) is allowed to flow into a capacitance (not shown) between the gate and drain of the FET 11a. By this phenomenon, the terminal voltage of the capacitance between the gate and drain drops to cause a reduction in the drain voltage that is the output voltage of the FET 11a.

As clearly understood by the above description, the falling slew rate can be represented by the following approximation by using the gate current (IG) and the capacitance between the gate and drain of the FET 11a.

Falling slew rate=Gate current (IG)/(Gate/drain capacitance of FET 11a) (4)

The above description has been given to describe the fact that, with respect to the transition state in which the FET 11a has reached the ON operation state from the OFF state, the relational expression of the falling slew rate is approximated by the equation (4). This is also hold in the same manner with respect to the rising slew rate in the transition state in which the FET 11a has reached the OFF state from the ON operation state. Since the operational principle is basically the same, the description thereof will not be repeated.

As clearly understood by the above-mentioned equation (4), the slew rate is not dependent on the threshold voltage of the FET 11a. Therefore, in a case where the current values of the constant-currents I1, I2 and I3 in the switching device driving unit 1 of the first embodiment of the present invention are designed so as not to be dependent on the output voltage (that is, the gate voltage of the FET 11a), the slew rate of the output voltage of the FET 11a is not varied in the switching device driving unit 1 of the first embodiment, even when the threshold voltage of the FET 11a is varied, so that variations of the switching speed can be suppressed.

As can be clearly understood by FIG. 2, in the switching device driving unit of the first embodiment, the gate current (IG) that determines the falling slew rate of the FET 11a from the OFF state to the ON operation corresponds to “IG” in the above-mentioned equation (1) . Moreover, the gate current (IG) that determines the rising slew rate of the FET 11a from the ON operation to the OFF state corresponds to “IG” in the above-mentioned equation (3). Therefore, upon setting the falling slew rate to a desired value, the current value (I1+I2) may be set to an appropriate value, by taking into consideration the gate/drain capacitance of the FET 11a that is a driving subject of the switching device driving unit 1. Moreover, upon setting the rising slew rate to a desired value, the current value (I3) may be set to an appropriate value in the same manner.

As shown in FIG. 2, by appropriately setting the delay time DT1 of the first delay circuit 2, in a completely driving state (in a load drive maintaining state) of the load 10 in the ON operation state of the FET 11a, the gate current IG required for maintaining the load driving state can be set to a value indicated the equation (2) , that is, IG=I1. In this manner, by setting the gate current (IG) to the current value (I1) in the load drive maintaining state, it becomes possible to prevent power losses caused by allowing an unnecessary gate current (IG) to flow into the gate terminal (G) of the FET 11a, in a constant ON operation state of the FET 11a in which a p-type region or a Schottky electrode is used for a gate.

In the switching device driving unit of the first embodiment, as shown in FIG. 2, after a lapse of a period of time (2*DS+DT2) from the time at which the gate control signal (GC) has become the L level from the H level, the signal (LD2) becomes the H level. As a result, the sink transistor 9 of the control current sink circuit 22 is turned ON so that the gate terminal (G) of the FET 11a is set to a low impedance state with a high current capability at a voltage close to 0V. With this structure, the switching device driving unit of the first embodiment makes it possible to maintain the gate voltage of the FET 11a at the voltage in the OFF state of the FET 11a, even in a state where a capacitive current is allowed to flow into the gate terminal (G) through the capacitance between the drain and gate of the FET 11a in the constant OFF operation state of the FET 11a. This effect is useful for avoiding a danger of shoot-through (through mode) in which two FETs 11a on a low-voltage side and a high-voltage side are simultaneously ON-operated, in a semi-bridge, an H-bridge, a three-phase inverter circuit or the like having a structure in which a pair of semiconductor apparatuses, each constituted by the switching device driving unit 1 of the first embodiment and the FET 11a in which a p-type region or a Schottky electrode is used for a gate, are installed in series with each other on two stages of the low voltage side and the high voltage side.

One of objects of the switching device driving unit of the present invention is to provide a circuit which can easily set a time profile in the gate current (IG) shown in FIG. 2, characterized by current values (I1, I2, I3) and delay times (DT1, DT2). The time profile of the gate current (IG) supposed to be obtained in the switching device driving unit of the first embodiment of the present invention is determined as follows.

(1) As described earlier, the current value of the gate current (IG) is determined by desired rising slew rate and falling slew rate, the gate current characteristics of the FET 11a at the time of load driving, and a capacitance between the gate and drain of the FET 11a. More specifically, the current value of the gate current (IG) is determined in the following manner.

(A) The current value (I1) is set to a gate current (IG) of the FET 11a required for maintaining load driving in the “load drive maintaining state” shown in FIG. 2, by taking into consideration variations in gate current characteristics of the FET 11a at the time of load driving.

(B) Supposing that the capacitance between the gate and drain of the FET 11a is “Cgd”, the current value (I1+I2) is determined by the following equation (5).

(I1+I2)=(Desired falling slew rate)*(Cgd) (5)

(C) The current value (I3) is determined by the following equation (6).

(I3)=(Desired rising slew rate)*(Cgd) (6)

In general, since the capacitance Cgd between the gate and drain varies depending on the voltage between the drain and source, the equations (5) and (6) sometimes do not exhibit the same capacitance value. By taking this point into consideration, the current values (I1, I2, I3) in the equations (5) and (6) need to be determined.

(2) Delay times (DT1, DT2) are determined by the current values (I1, I2, I3) of the constant-current supplies 14, 15 and 16, the capacitance (Cgd) between the gate and drain of the FET 11a, the capacitance (Cgs) between the gate and source of the FET 11a, the gate voltage characteristics at the time of load driving, and variation tolerances of these factors. More specifically, the delay times (DT1, DT2) are determined in the following manner.

(A) The delay time (DT1) is obtained by the following equations (7) and (8).

DT1={(VS−0V)/(Desired falling slew rate)+Ton+ΔTon} (7)

Ton=(VGSon*(Cgs+Cgd))/(I1+I2) (8)

In the equations (7) and (8), as shown in FIG. 2, “Ton” represents a period of time required for the gate voltage VGS to reach a gate voltage VGSon at which the FET 11a is turned ON, from 0 V. Moreover, “ΔTon” represents a tolerance of Ton that is determined by variation tolerances of the “VGSon”, “Cgs”, “Cgd”, “I1” and “I2”. In this case, “VS” represents a voltage of the power supply 12, and “Cgs” represents a capacitance between the gate and source of the FET 11a.

(B) The delay time (DT2) is obtained by the following equations (9) and (10).

DT2={(VS−0V)/(Desired rising slew rate)+Toff+ΔToff} (9)

Toff={(VGS(I1)−VGSon)*(Cgs+Cgd)}/ (I3) (10)

In the equations (9) and (10), as shown in FIG. 2, “Toff” represents a period of time required for the gate voltage VGS to reach the aforementioned VGSon from a VGS (I1) to be described later. Moreover, “ΔToff” represents a tolerance of Toff that is determined by variation tolerances of the “VGS (I1)”, “VGSon”, “Cgs”, “Cgd”, and “I3”. In this case, “VGS” represents a voltage between the gate and source of the FET 11a at the time when the gate current (IG) equals to the current value (I1).

As described above, by finding the setting values of the current values (I1, I2, I3) of the constant-current sources 14, 15 and 16, and delay times (DT1, DT2) , the time profile of the gate current (IG) of the FET 11a in the switching device driving unit of the first embodiment of the present invention can be easily set. As a result, by allowing the switching device driving unit of the first embodiment to drive control the switching device, variations in slew rate of the output voltage of the FET 11a can be suppressed even when the threshold voltage of the FET 11a serving as a switching device in which a p-type region or a Schottky electrode is used for a gate is varied, that is, variations in switching speed can be suppressed, so that it becomes possible to prevent a power loss caused by an unnecessary gate current during a constant ON operation state of the FET 11a and consequently to easily set a desired slew rate.

In the switching device driving unit 1 described in the first embodiment and the semiconductor apparatus provided with the switching device 11 that is a driving subject thereof, the superior effects of the switching device driving unit 1 can be effectively maintained, thereby making it possible to provide a device having high reliability, with its energy consumption being cut effectively.

### Second Embodiment

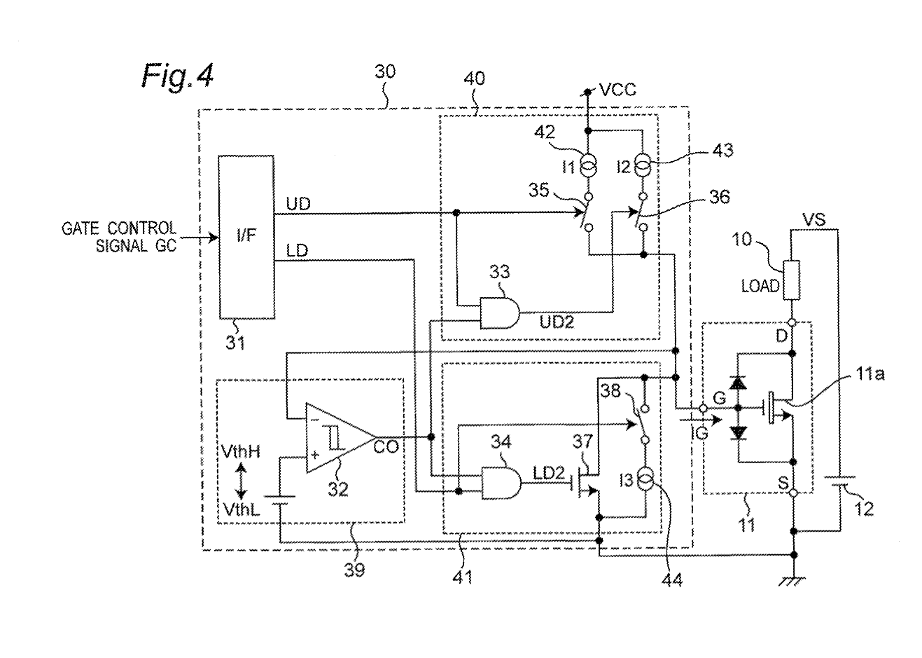

FIG. 4 is a block diagram that illustrates a specific structure of a second embodiment of a switching device driving unit and a semiconductor apparatus in accordance with the present invention. Referring to FIG. 4, the following description will discuss the second embodiment of a switching device driving unit and a semiconductor apparatus in accordance with the present invention. In the description of the switching device driving unit and semiconductor apparatus of the second embodiment, those members having the same functions and structures as those of the switching device driving unit and semiconductor apparatus of the first embodiment are indicated by the same reference numerals, and the description thereof will not be repeated.

A switching device driving unit 30, which ON/OFF drives (carries out switching operations) a switching device 11, is constituted by an I/F (interface) circuit 31 to which a gate control signal (GC) is inputted, a control current source circuit 40 to which a signal (US) is inputted from the I/F circuit 31 and which is connected to a power supply side (VCC), a control current sink circuit 41 to which a signal (LD) is inputted from the I/F circuit 31 and which is connected to the ground, and a comparator 39 having a hysteresis comparator 32 provided with two threshold voltages (VthH, VthL). Outputs from the control current source circuit 40 and the control current sink circuit 41 are inputted to the gate terminal (G) of the switching device 11 as the outputs of the switching device driving unit 30. In the second embodiment, the switching device 11 is exemplified by an FET 11a in which a p-type region or a Schottky electrode is used for a gate; however, a bipolar transistor may be applicable as the switching device 11 that is ON/OFF driven by the switching device driving unit of the present invention.

As described above, the output terminal of the switching device driving unit 30 of the second embodiment is connected to the gate terminal (G) of the FET 11a in which a p-type region or a Schottky electrode is used for a gate, and to the input terminal of the switching device driving unit 30, a gate control signal (GC) which carries out a source/sink output control of the gate current (IG) so as to ON/OFF drive the FET 11a is inputted to the gate terminal (G) of the FET 11a.

In the switching device driving unit 30 of the second embodiment, the I/F circuit 31 is allowed to generates an input driving signal (UD) for a control current source circuit 40 and an input driving signal (LD) for the control current sink circuit 41 by the gate control signal (GC). In response to the input driving signal (UD) from the I/F circuit 31 and a signal from the comparator 39, the control current source circuit 40 source-outputs a. gate current (IG) to the gate terminal (G) of the FET 11a. In response to the input driving signal (LD) from the I/F circuit 31 and a signal from the comparator 39, the control current sink circuit 41 sink-outputs a gate current (IG) to the gate terminal (G) of the FET 11a. The comparator 39 is provided with a hysteresis comparator 32 having two threshold voltages (VthH, VthL).

The voltage (gate terminal voltage) of the gate terminal of the FET 11a is inputted to the inversion input terminal (−) of the hysteresis comparator 32. Two threshold voltages are inputted to the other input terminal (+) of the hysteresis comparator 32 so that the hysteresis comparator 32 compares the gate terminal voltage with the two threshold voltages. The hysteresis comparator 32 outputs a signal (CO) corresponding to the result of the comparisons to the control current source circuit 40 and the control current sink circuit 41. The respective output terminals of the control current source circuit 40 and the control current sink circuit 41 are connected to the gate terminal (G) of the FET 11a through the output terminal of the switching device driving unit 30.

The control current source circuit 40 is provided with two constant-current supplies 42 and 43. A switch circuit 35, which is drive-controlled by the input driving signal (UD), is installed on one of the constant-current supplies 42 so that a constant-current (I1) of the constant-current supply 42 is source-outputted to the gate terminal (G) of the FET 11a in response to the input driving signal (UD). A switch circuit 36, which is drive-controlled by an input driving signal (UD2) obtained by waveform-shaping from the input driving signal (UD) and the signal (CO) from the hysteresis comparator 32, is installed on the other constant-current supply 43. The switch circuit 36 is drive-controlled by the input driving signal (UD2) so that a constant-current (I2) of the constant-current supply 36 is source-outputted to the gate terminal (G) of the FET 11a simultaneously with the constant-current (I1) , and so that the supply to the gate terminal (G) of the FET 11a is cut off in response to the signal (CO) from the hysteresis comparator 32.

In FIG. 4, the circuit structure for source-outputting to the gate terminal (G) of the FET 11a by using the two constant-current supplies 42 and 43 and the switching circuits 35 and 36 of the control current source circuit 40 in the switching device driving unit 30 of the second embodiment has been described; however, more specifically, the same circuit structure described in the first embodiment as shown in FIG. 3 can be exemplified.

As described earlier, the circuit structure shown in FIG. 3 is provided with two constant-current supplies (I1, I2) and a plurality of bipolar-type transistors, and has a structure to which driving signals (UD, UD2) are inputted so that a gate current (IG) is outputted from one current output terminal. FIG. 3 exemplifies a structure in which the gate current (IG) is controlled by the driving signals (UD, UD2) by the use of the plurality of the bipolar-type transistors; however, these bipolar-type transistors maybe replaced by MOS-type transistors and the same effects can be obtained.

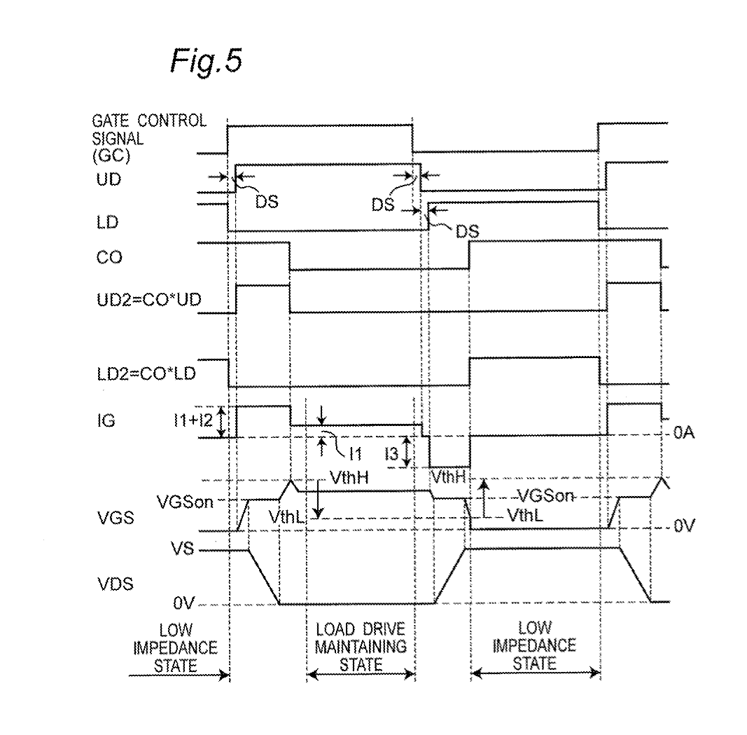

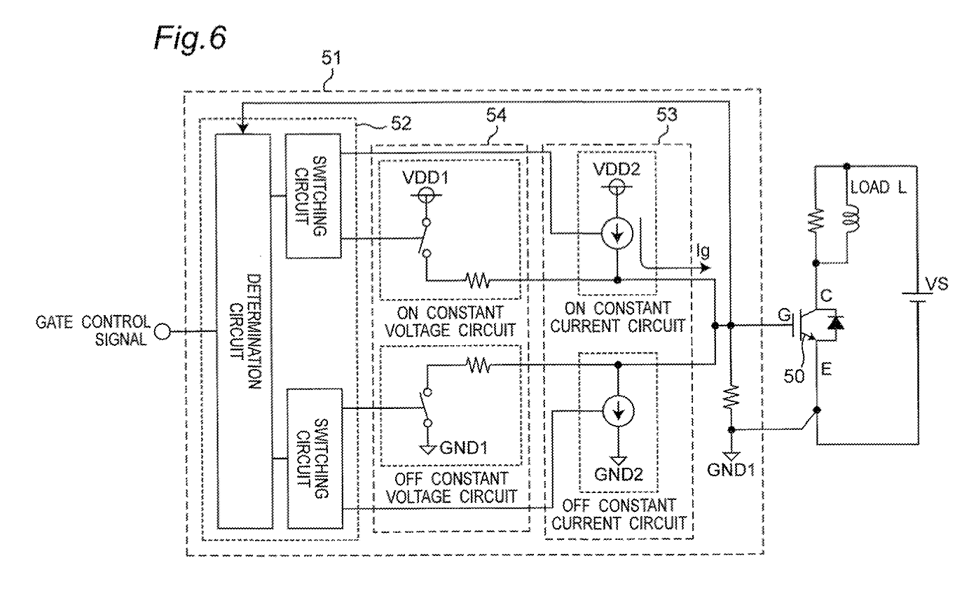

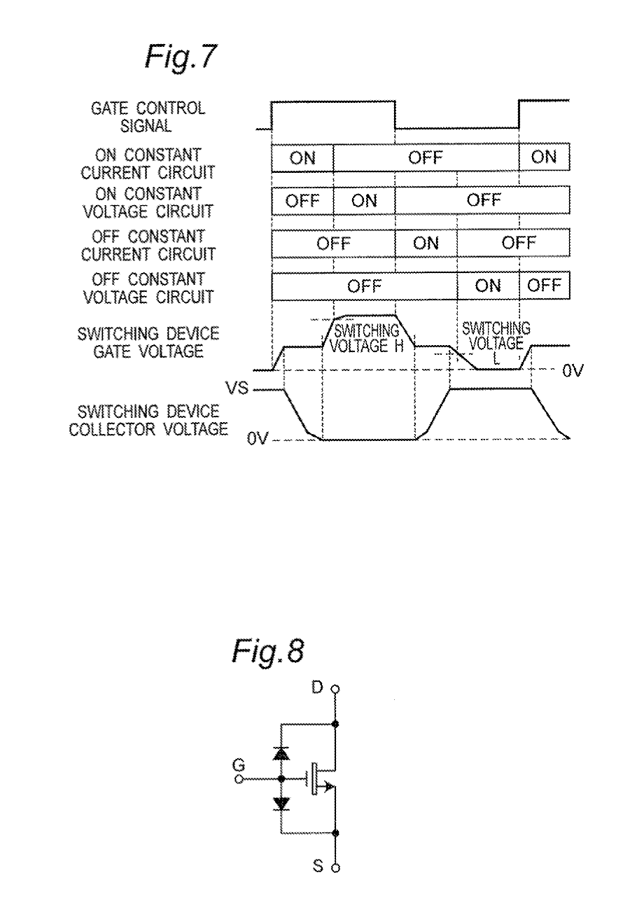

FIG. 5 is a timing waveform diagram that shows a relationship among the gate control signal (GC), the driving signals (UD, UD2) , the gate current (IG), the constant-currents (I1, I2) and the like. By using the timing waveform diagram of FIG. 5, the following description will discuss a mechanism by which the gate current (IG) of the gate terminal (G) of the FET 11a serving as the switching device 11 is source-outputted, in detail.

in the switching device driving unit 30 of the second embodiment of the present invention, the timing waveform diagram of FIG. 5 exemplifies a structure in which, when the gate control signal (GC) is in the 8 level, the gate current (IG) is source-outputted; however, another structure in which, when the gate control signal (GC) is in the L level, the gate current (IG) is source-outputted may be adopted.

Moreover, in the switching device driving unit 30 of the second embodiment, the polarity of each of signals shown in FIG. 5 is not necessarily required to be the same polarity as that indicated in FIG. 5, but may have a reversed polarity to that shown therein; alternatively, the relative polarity relationship among the respective signals is not necessarily required to be the same polarity relationship as that indicated in FIG. 5. This is because the specific polarity relationship among these signals relates to means for achieving the object of the present invention, that is, circuit designing for the control current source circuit 40, the control current sink circuit 41 and the hysteresis comparator 32, and does not relate to the object of the switching device driving unit 30 of the present invention.

As shown in the timing waveform diagram of FIG. 5, in a case where the gate control signal (GC) becomes a H level, the I/F circuit 31 sets the input driving signal (LD) of the control current sink circuit 41 to a L level, and after a lapse of a predetermined period of delay time DS from that point of time, it also sets the input driving signal (LD) of the control current source circuit 40 to the H level . In the control current source circuit 94 and the control current sink circuit 41, when the input driving signals (UD, LD) are in the H level, the respective operations are made active so that the respective constant-currents I1, I2 and I3 are ready to be outputted.

The reason why the I/F circuit 31 carries out a switching process with a shift by the delay time DS so as not to be overlapped, without simultaneously switching the polarities of the respective input driving signals (UD, LD) is because it is necessary to avoid the control current source circuit 40 and the control current sink circuit 41 from simultaneously outputting constant-currents. However, in this case where no problems are raised even if the constant-currents are simultaneously outputted by the control current source circuit 40 and the control current sink circuit 41, simultaneously as the gate control signal (GC) becomes the H level, the TIE circuit 31 may set the input driving signal (LD) of the control current sink circuit 41 to the L level, with the input driving signal (UD) of the control current source circuit 40 being simultaneously set to the H level.

When the input driving signal (UD) is set td the H level, the constant-current I1 is outputted to the gate terminal (G) of the FEY 11a through the switching circuit 35. The input driving signal (UD) and the signal (CO) of the hysteresis comparator 32 are inputted to a 2-input AND circuit 33. A driving signal (UD2), shaped based on an AND logic in the 2-input AND circuit 33, is set to the H level simultaneously with the rising edge of the input driving signal (UD), and becomes the L level when the gate terminal voltage of the FET 11a exceeds the threshold voltage (VthH) of the H level of the hysteresis comparator 32. Only during a period in which the signal (UD2) is in the H level, the constant-current I2 is outputted to the gate terminal (G) of the FET 11a.

After a lapse of the delay time DS after the gate control signal (GC) has become the H level as the results of the functions as described above, a gate current (IG) indicated by the following equation (11) is allowed to flow into the gate terminal (G) of the FET 11a.

IG=I1+I2 (11)

In a case where, after the gate current (IG) has been allowed to flow into the gate terminal (G) of the FET 11a as described above, the gate terminal voltage of the FET 11a exceeds the threshold voltage (VthH) of the H level of the hysteresis comparator 32, a gate current (IG) indicated by the following equation (12) is allowed to flow into the gate terminal (G).

IG=I1 (12)

As described earlier, during the period of the H level of the gate control signal (GC) , the input driving signal (LD) becomes the L level so that the constant-current I3 of the control current sink circuit 41 is not outputted to the gate terminal (G) of the FET 11a.

Next, when the gate control signal (GC) changes to the L level, the input driving signal (UD) becomes the L level after a lapse of the delay time DS, and the input driving signal (LD) becomes the H level after the delay time DS has further elapsed. This is because, in the same manner as described earlier, it is necessary to avoid the control current sink circuit 41 and the control current source circuit 40 from being simultaneously outputted. If no problems are raised even when the control current sink circuit 41 and the control current source circuit 40 are allowed to simultaneously output, the I/F circuit 31 may set the input driving signal (UD) of the control current source circuit 40 to the L level, with the input driving signal (LD) of the control current sink circuit 41 being simultaneously set to the H level, when the gate control signal (GC) becomes the L level.

As clearly understood by FIG. 4, the driving signal (UD2) is always set to the L level when the input driving signal (UD) becomes the L level so that the constant-currents I1 and I2 of the control current source circuit 40 are not outputted to the gate terminal (G) of the FET 11a. In contrast, when the input driving signal (LD) becomes the H level, the constant-current I3 of the control current sink circuit 41 is outputted to the gate terminal (G) of the FET 11a.

The input driving signal (LD) and the signal (CO) of the hysteresis comparator 32 are inputted to the two-input AND circuit 34 so that a driving signal (LD2) is formed by the AND logic. Although the driving signal (LD2) thus formed is still kept in the L level at the time when the input driving signal (LD) rises to the H level, it becomes the H level when the gate terminal voltage of the FET 11a becomes lower than the threshold voltage (VthL) of the L level of the hysteresis comparator 32. Thereafter, simultaneously as the input driving signal (LD) becomes the L level by the transition of the gate control signal (GC) to the H level, the driving signal (LD2) becomes the L level.

Only during the H level of the driving signal (LD2) , the gate voltage of the sink transistor 37 becomes the H level, thereby setting the sink transistor 37 to the ON state.

After a lapse of two times the delay time DS after the gate control signal (GC) has become the L level as the results of the functions as described above, a gate current (IG) indicated by the following equation (13) is drawn from the gate terminal (G) of the FET 11a.

IG=I3 (13)

In a case where, after the gate current (IG) has been drawn from the gate terminal (G) of the FET 11a as described above, the gate terminal voltage of the FET 11a becomes lower than the threshold voltage (VthL) of the L level of the hysteresis comparator 32, the sink transistor 37 is set to the ON state. As a result, the gate terminal (G) of the FET 11a is brought to a low impedance state having a high sink current capability so as to be fixed to a virtually GND voltage.

In the switching device driving unit 30 of the second embodiment of the present invention, the values of the constant-currents I1, I2 and I3, and the threshold voltages (VthH, VthL) of the H level and L level of the hysteresis comparator are designed to be desirably set. Therefore, the switching device driving unit 30 of the second embodiment of the present invention makes it possible to suppress variations in slew rate of the output voltage of the FET 11a, even when the threshold voltage of the FET 11a in which a p-type region or a Schottky electrode is used for a gate is varied upon transition from the OFF state to the ON state, or from the ON State to the OFF state, thereby making it possible to suppress variations in switching speed.

Moreover, in the switching device driving unit 30 of the second embodiment constructed as described above, it is possible to easily set the slew rate of the output voltage to a desired value, upon transition from the OFF state to the ON state or upon transition from the ON state to the OFF state of the FET 11a.

Furthermore, in the switching device driving unit 30 of the second embodiment, by the constant ON operation state of the FET 11a serving as the switching device, an unnecessary gate current (IG) is prevented from flowing to the gate terminal (G) of the FET 11a so that a power loss can be prevent

In the switching device driving unit 30 of the second embodiment, the following description will discuss the fact that the power loss in the constant ON operation state of the switching device can be prevented.

With respect to operation principles based on which variations of the slew rate of the output voltage of the FET 11a in the transit operation state from the ON state to the OFF state, or from the OFF state to the ON state, can be suppressed even when the threshold voltage of the FET 11a serving as a switching device is varied, that is, the variations of the switching speed can be suppressed, as well as based on which the slew rate of the output voltage at the time of the transit operation from the OFF state to the ON state of the FET 11a or from the ON state to the OFF state thereof can be easily set to a desired value, the same operation principles described in the first embodiment can be applied; therefore, the description thereof will not be repeated.

Therefore, the following description will discuss only the fact that, in the constant ON operation state of the FET 11a serving as switching device, it becomes possible to prevent a power loss caused by allowing an unnecessary gate current (IG) to flow through the gate terminal (G) of the FET 11a.

When, as shown in FIG. 5, upon completion of the transit operation from the OFF state to the ON state of the FET 11a, “a load drive maintaining state” shown in FIG. 5 has been at the drain voltage that is the output voltage of the FET 11a is secured to virtually 0V. For this reason, although, during the transit period from the OFF to ON of the gate voltage of the FET 11a, a gate voltage (IG), which has been set to the voltage “VDSon”, is then allowed to again charge the capacitance of the gate terminal (GC) because the drain voltage is then set to 0 V, thereby allowing the gate voltage to rise. When the gate voltage has exceeded the threshold value (VthH) of the H level of the hysteresis comparator 32, the driving signal (UD2) becomes the L level so that the gate current (IG) is set to the current value (I1) as indicated by the equation (I2).

Therefore, while the relationship of the equation (11) used for setting the gate current (IG) to determine a desired falling slew rate is being satisfied, that is, while the relationship of IG=I1+I2 is being satisfied, the gate current (IG), required for the load drive maintaining state after completion of the transit operation, is Set by using (IG=I1), indicated by the equation (12), so that in the constant ON operation state of the FET 11a, it becomes possible to prevent a power loss caused by allowing an unnecessary gate current (IG) to flow through the gate terminal (G) of the FET 11a.

In this case, however, the threshold voltage (VthH) of the H level of the hysteresis comparator 32 needs to be set to a voltage higher than the voltage (VDSon).

Moreover, as shown in FIG. 5, after the gate control signal (GC) has been changed from the H level to the L level, the current value (IG=I3), indicated by the equation (13), is drawn from the gate terminal (G) of the FET 11a so that the gate voltage of the FET 11a starts dropping down. Operations thereafter are carried out base upon the same operation principles as described earlier. However, the operational polarity is reversed. Although the voltage (VDSon) is maintained during the transit period from the ON state to the OFF state of the gate voltage, the gate current (IG) is again allowed to discharge the capacitance of the gate terminal (G) because the drain voltage is then secured to the voltage (VS), thereby allowing the gate voltage to drop down.

In this case, the threshold voltage (VthL) of the L level of the hysteresis comparator 32 is preliminarily set to a voltage lower than the voltage (VGSon). Since the threshold voltage (VthL) of the L level is set in this manner, the signal (LD2) becomes the H level when the gate voltage becomes lower than the threshold voltage (VthL) of the L level of the hysteresis comparator 32, and the sink transistor 37 of the control current sink circuit 41 is consequently turned ON so that the gate voltage is set to a low impedance state with a high current capability at a voltage close to 0V. In a case where the FET 11a is consequently set to the constant OFF operation state, even in a state where a capacitive current is allowed to flow into the gate terminal (G) through the capacitance between the drain and gate of the FET 11a, the gate voltage of the FET 11a can be maintained in the OFF state voltage of the FET 11a. This effect is useful for avoiding a danger of shoot-through (through mode) in which two FETs 11a on a low-voltage side and a high-voltage side are simultaneously ON-operated, in a semi-bridge, an H-bridge, a three-phase inverter circuit or the like having a structure in which a pair of semiconductor apparatuses, each constituted by the switching device driving unit 30 of the second embodiment and the FET 11a in which a p-type region or a Schottky electrode is used for a gate, are installed in series with each other on two stages of the low voltage side and high voltage side.

One of objects of the switching device driving unit of the present invention is to provide a circuit which can easily set current values (I1, I2, I3) in the gate current (10) shown in FIG. 5 and threshold voltages (VthH, VthL) of the hysteresis comparator 32. The current values (I1, I2, I3) and threshold voltages (VthH, VthL) to be assumed in the switching device driving unit of the second embodiment of the present invention are determined as follows.

(1) As described earlier, the current value of the gate current (IG) is determined by desired rising slew rate and falling slew rate, the gate current characteristics of the FET 11a at the time of load driving, and a capacitance between the gate and drain of the FET 11a. More specifically, the current value of the gate current (IG) is determined in the following manner.

(A) The current value (II) is set to a gate current (IG) of the FET 11a required for maintaining load driving in the “load drive maintaining state” shown in FIG. 5, by taking into consideration variations in gate current characteristics of the FET 11a at the time of load driving.

(B) Supposing that the capacitance between the gate and drain of the FET 11a is “Cgd”, the current value (I1+I2) is determined by the following equation (14).

I1+I2=(Desired falling slew rate)*(Cgd) (14)

(C) The current value (I3) is determined by the following equation (15).

I3=(Desired rising slew rate)*(Cgd) (15)

In general, since the capacitance Cgd between the gate and drain varies depending on the voltage between the drain and source, the “Cad's” in the equations (14) and (15) sometimes do not provide the same capacitance value. By taking this point into consideration, the current values (I1, I2, I3) in the equations (14) and (15) need to be determined.

(2) The threshold voltages (VthH, VthL) are determined by the gate voltage characteristics at the time of load driving of the FET 11a, and variation tolerances of these factors. More specifically, the threshold voltages (VthH, VthL) are determined in the following manner.

(A) The threshold voltage (VthH) of the H level is obtained by the following equation (16).

VthH=VGS(I1)+ΔVGS(I1) (16)

In the equation (16), “VGS(I1)” represents a voltage between the gate and source of the FET 11a at the time when the gate current (IG) is set to the current value (I1), and corresponds to the voltage between the gate and source of the FET 11a required for maintaining load driving in the “load drive maintaining state” shown in FIG. 5. Moreover, “ΔVGS(I1)” represents a variation tolerance of the VGS(I1).

(B) The threshold voltage (VthL) of the L level is obtained by using “VGS(I1)” and “ΔVGS(I1)” in the same manner as in the threshold voltage (VthH) of the H level as described above.

VthL=VGSon−ΔVGSon (17)

In the equation (17), “VGSon” represents a gate voltage at which the FET 11a starts an ON operation, as shown in FIG. 5. Moreover, “ΔVGS(I1)” represents a variation tolerance of the VGS(I1).

As described above, by finding the setting values of the current values (I1, I2, I3) of the constant-current sources 42, 43, 44, and threshold voltages (VthH, VthL) of the hysteresis comparator 32, the time profile of the gate current (IG) of the FET 11a in the switching device driving unit of the second embodiment of the present invention can be easily set to desired states. As a result, by allowing the switching device driving unit 30 of the second embodiment to drive control the switching device, variations in slew rate of the output voltage of the FET can be suppressed even when the threshold voltage of the FET 11a serving as a switching device in which a p-type region or a Schottky electrode is used for, a gate is varied, that is, variations in switching speed, can be suppressed. Moreover, the switching device driving unit 30 of the second embodiment having this structure makes it possible to prevent a power loss caused by an unnecessary gate current during a constant ON operation state of the FET 11a and consequently to easily set a desired slew rate.

In the switching device driving unit 30 and the semiconductor apparatus provided with the switching device 11 that is a driving subject thereof, described in the second embodiment, the superior effects of the switching device driving unit 30 can be effectively maintained, thereby making it possible to provide a device having high reliability, with its energy consumption being cut effectively.

In the first embodiment and the second embodiment described above, the structure in which each of the control current source circuits (21 and 40) is provided with the two constant-current supplies (14, 15 as well as 42, 43) has been described; however, the number of the constant-current supplies of the present invention are not intended to be limited to two, and the structure may be configured in which the current value can be altered step by step so as to appropriately maintain the ON operation state with a power as small as possible in accordance with the characteristics of the switching device.

As described above, the switching device driving unit of the present invention to be installed in a semiconductor integrated circuit device has such an effect that, even when the threshold voltage of the switching device is varied, variations in switching speed of the output voltage of the switching device can be suppressed, and the switching device driving unit is useful in particular when an FET in which a p-type region or a Schottky electrode is used for a gate, or a bipolar transistor is used as the switching device.

In accordance with the switching device driving unit of the present invention, it becomes possible to prevent a power loss caused by causing an unnecessary current to flow through the gate terminal or the base terminal of the switching device in a constant ON operation state of the switching device, and also to easily set the slew rate of the output voltage to a desired value upon transition from the OFF state to the ON state or from the ON state to the OFF state of the switching device.

Moreover, in accordance with the switching device driving unit of the present invention, when the switching device is brought into a constant OFF operation state, even in a case where a capacitive current flows into the gate through a capacitance between the drain and the gate of the switching device, the gate voltage of the switching device can be maintained at a voltage of the OFF state. This structure is significantly useful for avoiding a danger of shoot-through (through mode) in which two switching devices on a low-voltage side and a high-voltage side are simultaneously ON-operated, in a semi-bridge, an H-bridge, a three-phase inverter circuit or the like having a structure in which a pair of semiconductor apparatuses, each constituted by a switching device driving unit and a switching device to be d ye-controlled, are installed in series with each other on two stages of the low voltage side and the high voltage side.

Effects similar to those described in the first embodiment and the second embodiment can be obtained not only in the case of using the FET in which the p-type region or the Schottky electrode is used for the gate as the switching device, but also in a case of using a bipolar transistor.

While the invention has been described in certain detail with reference to the specific embodiments thereof, the contents of the disclosure of the preferred embodiments may be modified in the detailed structures thereof, and the combinations of the respective components and changes in the orders can be made therein without departing from the spirit and scope of the claims of the present invention.

The present invention provides a switching device driving unit useful as a switching device driving unit to be installed in a semiconductor integrated circuit device or the like, and the switching device driving unit is useful in particular when an FET in which a p-type region or a Schottky electrode is used for a gate or a bipolar transistor is used as a switching device.

1. A switching device driving unit, which is connected to a gate or a base of a switching device that requires a gate current or a base current so as to drive a load, and outputs a driving current for ON/OFF operating the switching device based on an inputted gate control signal to the gate or the base, the switching device driving unit comprising:
a control current source circuit that is connected to a power supply side, and source-outputs a driving current to the gate or the base in response to an H level or an L level of the gate control signal;
a control current sink circuit that is connected to a ground side, and sink-outputs a driving current to the gate or the base in response to the L level or the H level of the gate control signal; and
an I/F circuit to which the gate control signal is inputted and which generates a first driving signal to be applied to the control current source circuit and a second driving signal to be applied to the control current sink circuit, wherein
based on the first driving signal, the control current source circuit sets the driving current to be source-outputted to the gate or the base of the switching device to different values in a stage of an initial ON operation of the switching operation in the switching device as well as in a stage after completion of the switching operation.

2. The switching device driving unit according to claim 1, wherein the switching device is an FET that uses a p-type region or a Schottky electrode for a gate, or a bipolar transistor.

3. The switching device driving unit according to claim 1, wherein in a first stage of initial output, the control current source circuit maintains the driving current to be source-outputted to the gate or the base of the switching device at a first constant-current value to be set so as to allow the switching operation of the switching device to have a predetermined speed, and in a second stage after a lapse of a predetermined delay period of time in an ON state after completion of the switching operation of the switching device, the control current source circuit alters the driving current to a second constant-current value having a value smaller than the first constant-current value, which is required for allowing the switching device to maintain load driving.

4. The switching device driving unit according to claim 3, wherein
the control current source circuit has a plurality of source-use constant-current supplies, and
a source output from one of the plurality of source-use constant-current supplies to the gate or the base of the switching device is ON/OFF controlled in response to a first driving signal inputted to the control current source circuit, and a source output from another one of the source-use constant-current supplies to the gate or the base of the switching device is ON/OFF controlled in response to a third driving signal that is obtained by waveform-shaping from the first driving signal inputted to the control current source circuit and a delay signal formed by delaying the first driving signal by a predetermined period of time.

5. The switching device driving unit according to claim 1, wherein the control current sink circuit maintains the driving current to be sink-outputted to the gate or the base of the switching device at a third constant-current value set so as to allow the switching operation of the switching device to have a predetermined speed in a first stage of initial output, and in a second stage after a lapse of a predetermined delay period of time in an OFF state after completion of the switching operation of the switching device, brings the driving current into a low impedance state having a current capability enough to absorb a capacitive current that flows through the gate or the base.

6. The switching device driving unit according to claim 5, wherein the control current sink circuit has a sink-use constant-current supply for discharging a charge of the gate or the base of the switching device, and a sink transistor that has the current capability enough to absorb the capacitive current that flows through the gate or the base of the switching device in the OFF state of the switching device, and
a sink output from the sink-use constant-current supply to the gate or the base of the switching device is ON/OFF controlled in response to the second driving signal inputted to the control current sink circuit, and the sink transistor is ON/OFF controlled by a fourth driving signal that is waveform-shaped from the second driving signal inputted to the control current sink circuit and a delay signal formed by delaying the second driving signal by a predetermined period of time.

7. The switching device driving unit according to claim 1, further comprising:
a hysteresis comparator that has two threshold voltages of a H level and a L level, and compares a gate voltage or a base voltage of the switching device inputted to an inversion input terminal with the threshold voltages, wherein
an output from the hysteresis comparator is inputted to the control current source circuit and the control current sink circuit so as to control, in response to the gate voltage or the base voltage of the switching device, a driving current from the control current source circuit and the control current sink circuit to the gate or the base of the switching device.

8. The switching device driving unit according to claim 7, wherein in a first stage of initial output, the control current source circuit maintains the driving current to be source-outputted to the gate or the base of the switching device at a first constant-current value to be set so as to allow the switching operation of the switching device to have a predetermined speed, and in a second stage in which the gate voltage or the base voltage of the switching device exceeds the threshold voltage of the H level of the hysteresis comparator, the control current source circuit alters the driving current to a second constant-current value smaller than the first constant-current value, which is required for allowing the switching device to maintain load driving.

9. The switching device driving unit according to claim 8, wherein
the control current source circuit has a plurality of source-use constant-current supplies, and
a source output from one of the plurality of source-use constant-current supplies to the gate or the base of the switching device is ON/OFF controlled in response to the first driving signal inputted to the control current source circuit, and a source output to the gate or the base of the switching device from another one of the source-use constant-current supplies is ON/OFF controlled when the gate voltage or the base voltage of the switching device exceeds the threshold voltage of the H level of the hysteresis comparator.

10. The switching device driving unit according to claim 7, wherein the control current sink circuit maintains the driving current to be sink-outputted to the gate or the base of the switching device at a third constant-current value to be set so as to allow the switching operation of the switching device to have a predetermined speed in a first stage of initial output, and in a second stage in which the gate voltage or the base voltage of the switching device is lower than the threshold voltage of the L level of the hysteresis comparator, brings the driving current into a low impedance state having a current capability enough to absorb a capacitive current that flows through the gate or the base when the switching device is in an OFF state.

11. The switching device driving unit according to claim 10, wherein
the control current sink circuit has a sink-use constant-current supply for discharging a charge of the gate or the base of the switching device, and a sink transistor that has the current capability enough to absorb the capacitive current that flows through the gate or the base of the switching device in an OFF state of the switching device, and
a sink output from the sink-use constant-current supply to the gate or the base of the switching device is ON/OFF controlled in response to the second driving signal inputted to the control current sink circuit, and the sink transistor is ON/OFF controlled when the gate voltage or the base voltage of the switching device is lower than the threshold voltage of the L level of the hysteresis comparator.

12. A semiconductor apparatus comprising: the switching device driving unit in claim 1 and a switching device that is drive-controlled by the switching device driving unit.
